(19) United States
(12) Patent Application Publication
(10) Pub. No.: US 2025/0266358 A1
(43) Pub. Date: Aug. 21, 2025

(54) SEMICONDUCTOR MEMORY DEVICE

(71) Applicant: Kioxia Corporation, Tokyo (JP)

(72) Inventors: Takeshi IRIMOTO, Iwakura Aichi (JP); Rikyu IKARIYAMA, Chigasaki Kanagawa (JP)

(73) Assignee: Kioxia Corporation, Tokyo (JP)

(21) Appl. No.: 18/827,403

(22) Filed: Sep. 6, 2024

(30) Foreign Application Priority Data
Feb. 21, 2024 (JP) 2024-024536

(51) Int. Cl. H01L 23/532; H10B 43/10; H10B 43/27; H10B 43/40

(52) U.S. Cl. CPC H01L 23/53295; H10B 43/10; H10B 43/27; H10B 43/40

(57) ABSTRACT

A semiconductor memory device of an embodiment includes: a first stacked body in which a plurality of conductive layers is stacked apart from each other in a stacking direction; a plate-shaped portion that extends in the first stacked body in the stacking direction and in a first direction intersecting the stacking direction, the plate-shaped portion dividing the first stacked body in a second direction intersecting the stacking direction and the first direction; and a pillar that extends in the first stacked body in the stacking direction and in which a memory cell is formed at each of intersection portions with at least some of the plurality of conductive layers, wherein between each the plurality of conductive layers, a first layer and a first insulating layer are disposed, the first layer including at least one of a Si—C bond or a Si—Si bond, the first insulating layer including a Si—O bond, the first insulating layer covering upper and lower surfaces of the first layer in the stacking direction and an end surface of the first layer facing a side wall of the plate-shaped portion LI, the first layer includes Si—C bonds or Si—Si bonds more than the first insulating layer, and the first insulating layer includes Si—O bonds more than the first layer.

### CROSS-REFERENCE TO RELATED APPLICATIONS

This application is based upon and claims the benefit of priority from Japanese Patent Application No. 2024-024536, filed on Feb. 21, 2024; the entire contents of which are incorporated herein by reference.

### FIELD

Embodiments described herein relate generally to a semiconductor memory device.

### BACKGROUND

When a semiconductor memory device such as a three-dimensional nonvolatile memory is manufactured, a process of alternately stacking a plurality of sacrificial layers and a plurality of insulating layers one by one, and forming a plurality of conductive layers in a gap between the insulating layers after removing the sacrificial layers may be included. However, after the removal of the sacrificial layers, the remaining insulating layers may be bent or the entire structure may be distorted.

### BRIEF DESCRIPTION OF THE DRAWINGS

FIGS. 1A and 1B are views illustrating a schematic configuration example of a semiconductor memory device according to a first embodiment;

FIGS. 2A to 2D are cross-sectional views along a Y direction illustrating an example of a configuration of the semiconductor memory device according to the first embodiment;

FIGS. 3A to 3C are schematic views describing stacked bodies included in the semiconductor memory device according to the first embodiment;

FIGS. 4A to 4D are views sequentially illustrating a part of a procedure of a method for manufacturing the semiconductor memory device according to the first embodiment;

FIGS. 5A to 5D are views sequentially illustrating a part of a procedure of a method for manufacturing the semiconductor memory device according to the first embodiment;

FIGS. 6A to 6C are views sequentially illustrating a part of a procedure of a method for manufacturing the semiconductor memory device according to the first embodiment;

FIGS. 7A to 7D are views sequentially illustrating a part of a procedure of a method for manufacturing the semiconductor memory device according to the first embodiment;

FIGS. 8A to 8C are views sequentially illustrating a part of a procedure of a method for manufacturing the semiconductor memory device according to the first embodiment;

FIGS. 9A to 9C are views sequentially illustrating a part of a procedure of a method for manufacturing the semiconductor memory device according to the first embodiment;

FIGS. 10A to 10C are views sequentially illustrating a part of a procedure of a method for manufacturing the semiconductor memory device according to the first embodiment;

FIGS. 11A to 11C are views sequentially illustrating a part of a procedure of a method for manufacturing the semiconductor memory device according to the first embodiment;

FIGS. 12A to 12C are views sequentially illustrating a part of a procedure of a method for manufacturing the semiconductor memory device according to the first embodiment;

FIGS. 13A to 13C are views sequentially illustrating a part of a procedure of a method for manufacturing the semiconductor memory device according to the first embodiment;

FIGS. 14A to 14C are views sequentially illustrating a part of a procedure of a method for manufacturing the semiconductor memory device according to the first embodiment; and

FIGS. 15A and 15C are views illustrating a schematic configuration example of a semiconductor memory device according to a second embodiment.

### DETAILED DESCRIPTION

A semiconductor memory device of an embodiment includes: a first stacked body in which a plurality of conductive layers is stacked apart from each other in a stacking direction; a plate-shaped portion that extends in the first stacked body in the stacking direction and in a first direction intersecting the stacking direction, the plate-shaped portion dividing the first stacked body in a second direction intersecting the stacking direction and the first direction; and a pillar that extends in the first stacked body in the stacking direction and in which a memory cell is formed at each of intersection portions with at least some of the plurality of conductive layers, wherein between each the plurality of conductive layers, a first layer and a first insulating layer are disposed, the first layer, the first layer including at least one of a Si—C bond or a Si—Si bond, the first insulating layer including a Si—O bond, the first insulating layer covering upper and lower surfaces of the first layer in the stacking direction and an end surface of the first layer facing a side wall of the plate-shaped portion, the first layer includes Si—C bonds more than the first insulating layer or the first layer includes Si—Si bonds more than the first insulating layer, and the first insulating layer includes more Si—O bonds than the first layer.

Hereinafter, embodiments of the present invention will be described in detail with reference to the drawings. Note that the present invention is not limited by the embodiments described below. In addition, constituent elements in the embodiments described below include those that can be easily assumed by those skilled in the art or those that are substantially the same.

### First Embodiment

Hereinafter, a first embodiment will be described in detail with reference to the drawings.

### (Configuration Example of Semiconductor Memory Device)

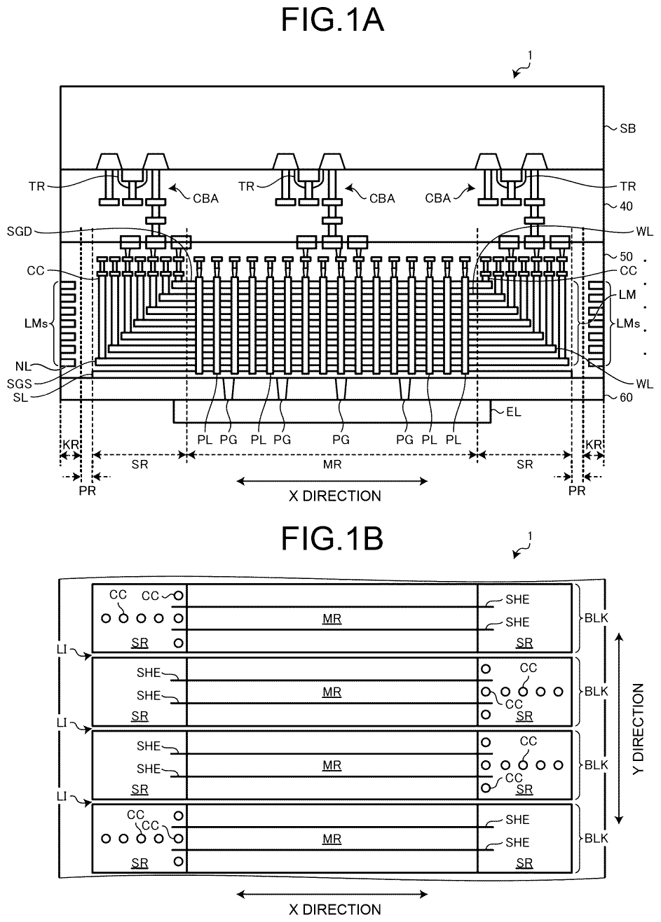

FIGS. 1A and 1B are views illustrating a schematic configuration example of a semiconductor memory device 1 according to a first embodiment. More specifically, FIG. 1A is a cross-sectional view of the semiconductor memory device 1 along an X direction, and FIG. 1B is a schematic plan view illustrating a layout of the semiconductor memory device 1.

However, in FIG. 1A, hatching is omitted in consideration of visibility of the drawing. In addition, in FIG. 1A, configurations that do not necessarily exist in the same cross section are illustrated, and a part of upper layer wiring and the like is omitted.

In addition, in the present specification, both the X direction and the Y direction are directions along the orientation of the surfaces of word lines WL, and the X direction and the Y direction are orthogonal to each other. In addition, the electrical lead-out direction of the word lines WL may be referred to as a first direction, and the first direction is a direction along the X direction. In addition, a direction intersecting the first direction may be referred to as a second direction, and the second direction is a direction along the Y direction. However, since the semiconductor memory device 1 may include a manufacturing error, the first direction and the second direction are not necessarily orthogonal to each other.

As illustrated in FIG. 1A, the semiconductor memory device 1 includes an electrode film EL, a source line SL, one or more select gate lines SGS, a plurality of word lines WL, one or more select gate lines SGD, and a semiconductor substrate SB on which peripheral circuits CBA are provided in order from the lower side of the drawing.

The source line SL is disposed on the electrode film EL via an insulating layer 60. A plurality of plugs PG is disposed in the insulating layer 60, and the source line SL and the electrode film EL maintain electrical conduction via the plugs PG. Although not illustrated, an electrode pad for supplying power and a signal from the outside to the semiconductor memory device 1 is provided in the same layer as the electrode film EL. A stacked body LM in which the select gate lines SGS, the plurality of word lines WL, and the select gate lines SGD are stacked in this order is disposed on the source line SL.

As illustrated in FIGS. 1A and 1B, a memory region MR is disposed at a central portion of the stacked body LM in the X direction, and staircase regions SR are disposed at both end portions of the stacked body LM in the X direction. The memory region MR and the staircase regions SR are divided into a plurality of regions by a plurality of plate-shaped contacts LI penetrating the stacked body LM and extending in the direction along the X direction.

Note that regions disposed between the plate-shaped contacts LI adjacent in the Y direction and including the memory region MR and the staircase regions SR are referred to as block regions BLK. As will be described below, the memory region MR includes a plurality of memory cells that holds data in a nonvolatile manner, and the above-described block region BLK is an erase unit of the data.

In addition, between the plate-shaped contacts LI adjacent in the Y direction, a plurality of separation layers SHE penetrating the select gate lines SGD and extending in the direction along the X direction is disposed. The plurality of separation layers SHE extends in the direction along the X direction over the entire memory region MR and reaches a part of the staircase regions SR at both end portions in the X direction.

In the memory region MR, a plurality of pillars PL penetrating the word lines WL and the select gate lines SGD and SGS in the stacking direction thereof is disposed. The lower ends of the pillars PL reach the source line SL. A plurality of memory cells is formed at intersection portions of the pillars PL and the word lines WL. As a result, the semiconductor memory device 1 is configured as, for example, a three-dimensional nonvolatile memory in which memory cells are three-dimensionally disposed in the memory region MR.

In the staircase regions SR, the plurality of word lines WL and the select gate lines SGD and SGS are processed in a staircase shape and terminate. At this time, as the distance from the memory region MR increases in the X direction, the plurality of word lines WL and the select gate lines SGD and SGS constituting a terrace portion shift from the upper layer side to the lower layer side, so that the height position of the terrace portion lowers toward the source line SL side.

Note that, in the present specification, the direction in which the terrace surfaces of the plurality of word lines WL and the select gate lines SGD and SGS face is defined as the upper side of the semiconductor memory device 1.

The separation layers SHE described above extend from the memory region MR to a portion of the staircase regions SR where the select gate lines SGD are processed into a staircase shape. As a result, in one block region BLK, the select gate lines SGD are separated into a plurality of regions. In other words, the separation layers SHE penetrate the portions above the plurality of word lines WL, so that these upper layer portions are partitioned into patterns of the plurality of select gate lines SGD.

Contacts CC connected to the word lines WL and the select gate lines SGD and SGS of layers are disposed at terrace portions of steps including the plurality of word lines WL and the select gate lines SGD and SGS. In the word lines WL and the select gate lines SGS, one contact CC is connected for each layer. In the select gate lines SGD, one contact CC is connected for each section separated by the separation layers SHE per layer.

Here, in one block region BLK, the plurality of contacts CC is disposed on one of the staircase regions SR on both sides in the X direction. In addition, when viewed on one side in the X direction, for example, the plurality of contacts CC is disposed every two block regions BLK.

That is, in the example of FIG. 1B, in the uppermost block region BLK in the drawing, a plurality of contacts CC is disposed, for example, in the staircase region SR on the left side in the drawing out of the staircase regions SR at both end portions in the X direction. In addition, in the block regions BLK one below and two below the above-described block region BLK, a plurality of contacts CC is disposed in the staircase region SR on the right side in the drawing out of the staircase regions SR at both end portions in the X direction. Further, in the lowermost block region BLK in the drawing, a plurality of contacts CC is disposed in the staircase region SR again on the left side in the drawing.

Accordingly, the contacts CC of the staircase regions SR at both end portions in the X direction illustrated in FIG. 1A belong to different block regions BLK, and are not actually located in the same cross section.

The word lines WL and the like stacked in multiple layers are individually lead out by these contacts CC. More specifically, a write voltage, a read voltage, and the like are applied from these contacts CC to the memory cells included in the memory region MR at the central portions of the plurality of word lines WL via the word lines WL at the same height positions as the memory cells.

The plurality of word lines WL, the select gate lines SGD and SGS, the pillars PL, and the contacts CC are covered with an insulating layer 50. The insulating layer 50 also extends around the stacked body LM. A peripheral region PR is disposed around the stacked body LM so as to surround the stacked body LM, and a kerf region KR surrounding the stacked body LM and the peripheral region PR is disposed further outside the peripheral region PR.

The kerf region KR corresponds to a dicing line when each semiconductor memory device 1 is cut out and singulated. The kerf region KR may include an alignment mark, which is not illustrated, and a stacked body LMs. As will be described below, the stacked body LMs is a portion separated from the stacked body LM described above during the process for manufacturing the semiconductor memory device 1, and has a structure in which a plurality of insulating layers NL is stacked instead of the word lines WL and the like described above.

The semiconductor substrate SB above the insulating layer 50 covering the stacked body LM is, for example, a silicon substrate or the like. The peripheral circuits CBA including transistors TR, wiring, and the like are disposed on the surface of the semiconductor substrate SB. Various voltages applied from the contacts CC to the memory cells are controlled by the peripheral circuits CBA electrically connected to the contacts CC. As a result, the peripheral circuits CBA control the electrical operation of the memory cells.

The peripheral circuits CBA are covered with an insulating layer 40, and the insulating layer 40 and the insulating layer 50 covering the plurality of word lines WL and the like are joined to form the semiconductor memory device 1 including the configurations of the plurality of word lines WL and the select gate lines SGD and SGS, the pillars PL, the contacts CC, and the like, and the peripheral circuits CBA.

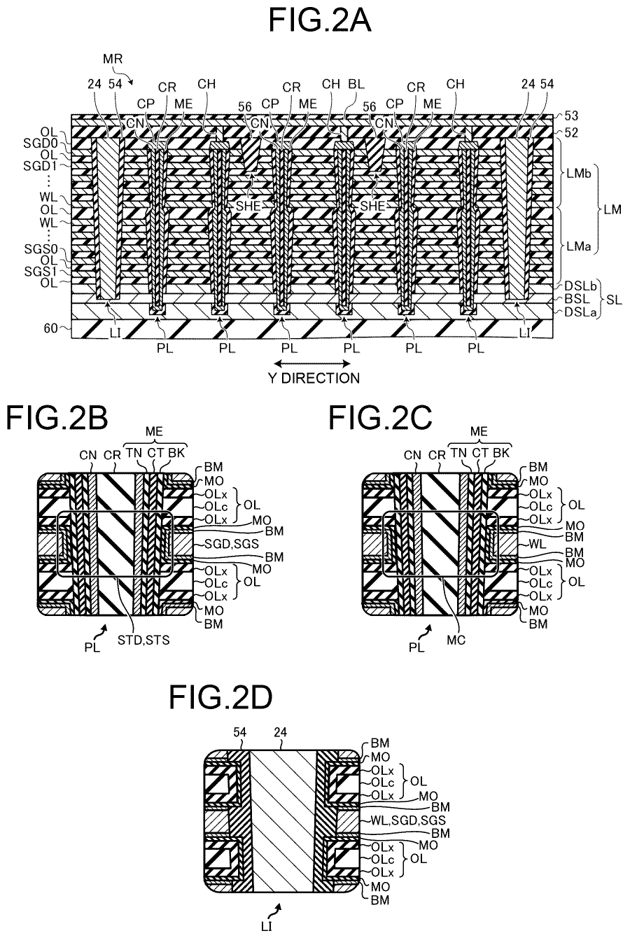

Next, a detailed configuration example of the semiconductor memory device 1 will be described with reference to FIGS. 2A to 2D. FIGS. 2A to 2D are cross-sectional views along a Y direction illustrating an example of a configuration of the semiconductor memory device 1 according to the first embodiment.

More specifically, FIG. 2A is a cross-sectional view of the memory region MR of the semiconductor memory device 1. In FIG. 2A, structures below insulating layer 60 and above an insulating layer 53 described below are omitted.

FIG. 2B is an enlarged cross-sectional view of the pillar PL at the height position of the select gate lines SGD and SGS. FIG. 2C is an enlarged cross-sectional view of the pillar PL at the height position of the word line WL. FIG. 2D is an enlarged cross-sectional view of the plate-shaped contact LI at the height position of the word line WL or the select gate lines SGD and SGS.

As illustrated in FIG. 2A, the source line SL has a multilayer structure in which, for example, a lower source line DSLa, an intermediate source line BSL, and an upper source line DSLb are stacked in this order on the insulating layer 60. The lower source line DSLa, the intermediate source line BSL, and the upper source line DSLb are, for example, polysilicon layers. Among them, at least the intermediate source line BSL may be a conductive polysilicon layer or the like in which impurities are diffused.

Note that the source line SL is connected to the peripheral circuits CBA via the electrode film EL by penetrating contacts, which are not illustrated, extending from the electrode film EL to the peripheral circuits CBA in the insulating layer 50 described above outside the stacked body LM.

The stacked body LM is disposed on the source line SL. The stacked body LM includes stacked bodies LMa and LMb in which a plurality of word lines WL and a plurality of insulating layers OL are alternately stacked one by one.

The stacked body LMa is disposed above the source line SL. A plurality of select gate lines SGS0 and SGS1 is disposed in this order from the upper layer side of the stacked body LMa via the insulating layers OL further below the lowermost word line WL of the stacked body LMa. The stacked body LMb is disposed on the stacked body LMa. A plurality of select gate lines SGD0 and SGD1 are disposed in this order from the upper layer side of the stacked body LMb via the insulating layers OL further above the uppermost word line WL of the stacked body LMb.

However, the number of word lines WL and select gate lines SGD and SGS stacked in the stacked body LM is arbitrary. The word lines WL and the select gate lines SGD and SGS are, for example, a tungsten layer or a molybdenum layer. The insulating layers OL are, for example, a silicon oxide layer including a silicon oxide layer doped with carbon as a core material. A detailed layer configuration of the insulating layers OL will be described below.

The upper surface of the stacked body LM is covered with an insulating layer 52. The insulating layer 52 is covered with the insulating layer 53. Each of the insulating layers 52 and 53 constitutes a part of the insulating layer 50 in FIG. 1A.

As described above, the stacked body LM is divided in the Y direction by the plurality of plate-shaped contacts LI. That is, the plate-shaped contacts LI are each arranged in the Y direction and extend in the stacking direction of the stacked body LM and in a direction along the X direction.

As described above, the plate-shaped contacts LI continuously extend in the stacked body LM from one end portion to the other end portion of the stacked body LM in the X direction. In addition, the plate-shaped contacts LI penetrate the stacked body LM and the upper source line DSLb and reach the intermediate source line BSL.

In addition, the plate-shaped contacts LI have, for example, a tapered shape in which the width in the Y direction decreases from the upper end portion toward the lower end portion. Alternatively, the plate-shaped contacts LI have, for example, a bowing shape in which the width in the Y direction is maximized at a predetermined position between the upper end portion and the lower end portion.

Each of the plate-shaped contacts LI includes an insulating layer 54 and a conductive layer 24. The insulating layer 54 is, for example, a silicon oxide layer or the like. The conductive layer 24 is, for example, a tungsten layer or a conductive polysilicon layer.

The insulating layer 54 covers the side walls of the plate-shaped contact LI facing each other in the Y direction. The conductive layer 24 is loaded inside the insulating layer 54, and electrically connected to the source line SL including the intermediate source line BSL. However, instead of the plate-shaped contact LI, a plate-shaped member filled with the insulating layer may penetrate the stacked body LM and extend in the direction along the X direction, thereby dividing the stacked body LM in the Y direction.

In addition, between the plate-shaped contacts LI adjacent in the Y direction, a plurality of separation layers SHE penetrating the upper layer portion of the stacked body LMb and extending in the direction along the X direction is disposed. These separation layers SHE are insulating layers 56 such as silicon oxide layers that penetrate the select gate lines SGD0 and SGD1 and reach the insulating layer OL immediately below the select gate line SGD1.

In other words, these separation layers SHE penetrating the upper layer portion of the stacked body LMb extend between the plate-shaped contacts LI in the X direction between the memory region MR and a part of the staircase regions SR, so that the upper layer portion of the stacked body LMb is partitioned into the select gate lines SGD0 and SGD1 described above.

In the memory region MR, the plurality of pillars PL penetrating the stacked body LM, the upper source line DSLb, and the intermediate source line BSL and reaching the lower source line DSLa is dispersedly disposed.

The plurality of pillars PL is disposed, for example, in a staggered manner when viewed from the stacking direction of the stacked body LM. Each pillar PL has, for example, a circular shape, an elliptical shape, an oblong shape (oval shape), or the like as a cross-sectional shape in a direction along the layer direction of the stacked body LM, that is, in a direction along the XY plane.

In addition, each of the pillars PL has a tapered shape in which the diameter and the cross-sectional area decrease from the upper layer side toward the lower layer side in a portion penetrating the stacked body LMa and a portion penetrating the stacked body LMb. Alternatively, each of the pillars PL has, for example, a bowing shape in which the diameter and the cross-sectional area are maximized at a predetermined position between the upper layer side and the lower layer side in a portion penetrating the stacked body LMa and a portion penetrating the stacked body LMb.

Each of the plurality of pillars PL includes a memory layer ME extending in the stacked body LM in the stacking direction, a channel layer CN penetrating the stacked body LM and connected to the intermediate source line BSL, a cap layer CP covering the upper surface of the channel layer CN, and a core layer CR serving as a core material of the pillar PL.

As illustrated in FIGS. 2B and 2C, the memory layer ME has a multilayer structure in which a block insulating layer BK, a charge storage layer CT, and a tunnel insulating layer TN are stacked in this order from the outer peripheral side of the pillar PL. More specifically, the memory layer ME is disposed on a side surface of the pillar PL except for the depth position of the intermediate source line BSL. In addition, the memory layer ME is also disposed on the bottom surface of the pillar PL reaching the depth of the lower source line DSLa.

The channel layer CN penetrates the stacked body LM, the upper source line DSLb, and the intermediate source line BSL inside the memory layer ME and reaches the depth of the lower source line DSLa. More specifically, the channel layer CN is disposed on the side surface and the bottom surface of the pillar PL together with the outermost memory layer ME. However, a part of the channel layer CN is exposed to the outermost periphery of the pillar PL at the depth position of the intermediate source line BSL, and a side surface of the channel layer CN is in contact with the intermediate source line BSL, so that the channel layer CN is electrically connected to the source line SL including the intermediate source line BSL. The core layer CR is loaded further inside the channel layer CN.

In addition, each of the plurality of pillars PL has the cap layer CP at the upper end portion. The cap layer CP is disposed at the upper end portion of the pillar PL so as to cover at least the upper end portion of the channel layer CN, and is connected to the channel layer CN. In addition, the cap layer CP is connected to a bit line BL disposed in the insulating layer 53 via plugs CH disposed in the insulating layer 52. The bit line BL extends above the stacked body LM in the direction along the Y direction so as to intersect with the lead-out direction of the word lines WL.

Note that, in FIG. 2A, the plugs CH are connected only to three pillars PL that penetrate the select gate lines SGD separated into three and are electrically connected to the bit line BL illustrated in FIG. 2A among the six pillars PL. The other pillars PL are connected to another bit line BL extending in the direction along the Y direction in parallel with the bit line BL illustrated in FIG. 2A via plugs CH, which are not illustrated in FIG. 2A, at positions different from the cross section illustrated in FIG. 2A.

The block insulating layer BK and the tunnel insulating layer TN of the memory layer ME, and the core layer CR are, for example, silicon oxide layers or the like. The charge storage layer CT of the memory layer ME is, for example, a silicon nitride layer or the like. The channel layer CN and the cap layer CP are semiconductor layers such as a polysilicon layer or an amorphous silicon layer.

As illustrated in FIG. 2C, with the above configuration, memory cells MC are formed in portions facing the individual word lines WL on the side surface of the pillar PL. When a predetermined voltage is applied from the word line WL, data is written to and read from the memory cell MC.

In addition, as illustrated in FIG. 2B, select gates STD are formed in portions where the side surface of the pillar PL faces the select gate lines SGD0 and SGD1 above the word lines WL. In addition, select gates STS are formed in portions where the side surface of the pillar PL faces the select gate lines SGS0 and SGS1 below the word lines WL.

When predetermined voltages are applied from the select gate lines SGD and SGS, the select gates STD and STS are turned on or off, and the memory cells MC of the pillar PL to which the select gates STD and STS belong can be brought into a selected state or a non-selected state.

Hereinafter, the detailed structure of each layer of the stacked body LM of the semiconductor memory device 1 of the first embodiment will be further described with reference to FIGS. 2B to 2D.

As illustrated in FIGS. 2B to 2D, on each of the plurality of word lines WL and the select gate lines SGD and SGS included in the stacked body LM, barrier metal layers BM and the metal element-containing layers MO are disposed in this order on the upper and lower surfaces in the stacking direction.

The barrier metal layer BM includes, for example, at least one layer of a titanium layer, a titanium nitride layer, a tantalum layer, a tantalum nitride layer, and a molybdenum nitride layer. As a result, the barrier metal layer BM suppresses diffusion of metal atoms such as tungsten or molybdenum constituting the word line WL or the like into another adjacent layer. The metal element-containing layer MO is, for example, an aluminum oxide (Al₂O₃) layer or the like, and functions as a block insulating layer in the memory cell MC.

As illustrated in FIGS. 2B and 2C, an end surface of the word line WL or the like facing the side wall of the pillar PL is also covered with the barrier metal layer BM and the metal element-containing layer MO in this order. On the other hand, as illustrated in FIG. 2D, an end surface of the word line WL or the like facing the side wall of the plate-shaped contact LI is not covered with the barrier metal layer BM and the metal element-containing layer MO, and is in direct contact with the side wall of the plate-shaped contact LI.

Note that the end surfaces of the word line WL and the select gate lines SGD and SGS facing the side wall of the plate-shaped contact LI and the barrier metal layers BM covering the upper and lower surfaces thereof are slightly retracted in a direction away from the plate-shaped contact LI with respect to the end surfaces of the insulating layers OL adjacent in the stacking direction. Thus, the insulating layer 54 covering the side wall of the plate-shaped contact LI protrudes to the retracted end surfaces of the word line WL and the like. That is, the insulating layer 54 on the side wall of the plate-shaped contact LI protrudes to both sides in the Y direction at the height position of each of the word lines WL and the select gate lines SGD and SGS.

As illustrated in FIGS. 2B to 2D, each of the plurality of insulating layers OL included in the stacked body LM includes a core layer OLc and insulating layers OLx sandwiching the core layer OLc in an up-down direction in the stacking direction. The core layer OLc is, for example, a carbon-doped silicon oxide layer, that is, a silicon carbonate layer. The insulating layer OLx is a silicon oxide layer or the like, and is a layer formed by oxidizing the surface of the core layer OLc as described below.

Here, each of the core layer OLc, which is a carbon-doped silicon oxide layer or the like, and the insulating layer OLx formed by oxidizing the core layer OLc may contain a Si—C bond and a Si—O bond in the layer. However, the Si—C bond in the insulating layer OLx is cut or replaced with the Si—O bond by the oxidation of the core layer OLc. Therefore, the core layer OLc contains more Si—C bonds than the insulating layer OLx, and the insulating layer OLx contains more Si—O bonds than the core layer OLc.

The contents of the Si—C bond and the Si—O bond in the core layer OLc and the insulating layer OLx can be measured by, for example, TEM-EESL in which transmission electron microscopy (TEM) is combined with electron energy-loss spectroscopy (EELS).

Note that it is preferable that the insulating layer OLx is oxidized to such an extent that the spectrum caused by the Si—C bond is not detected in the measurement by TEM-EESL.

In addition, the carbon content of the core layer OLc is preferably 1 atom % or more. As a result, the Young's modulus of the core layer OLc can be set to, for example, 100 Gpa or more, and can be made higher than that of the insulating layer OLx. The carbon content in the core layer OLc can be measured by, for example, Auger electron spectroscopy (AES) or the like.

As illustrated in FIG. 2D, the end surface of the core layer OLc facing the side wall of the plate-shaped contact LI is covered with the insulating layer OLx. The insulating layer OLx covering the end surface of the core layer OLc is further covered with the metal element-containing layer MO described above. That is, the metal element-containing layer MO extends at the interface between the barrier metal layer BM covering the word line WL and the insulating layer OL, and continuously extends to the interface between the side wall of the plate-shaped contact LI and the end surface of the insulating layer OL. As a result, the core layer OLc of the insulating layer OL faces the side wall of the plate-shaped contact LI via the insulating layer OLx and the metal element-containing layer MO.

On the other hand, as illustrated in FIGS. 2B and 2C, the end surface of the core layer OLc facing the side wall of the pillar PL is not covered with the insulating layer OLx, the metal element-containing layer MO, or the like, and is in direct contact with the side wall of the pillar PL.

In each of the insulating layers OL, the insulating layer OLx has a substantially uniform layer thickness on both the upper and lower surfaces of the core layer OLc and the end surface of the core layer OLc facing the side wall of the plate-shaped contact LI. That is, the thickness in the stacking direction of the insulating layer OLx on the upper surface of the core layer OLc, the thickness in the stacking direction of the insulating layer OLx on the lower surface of the core layer OLc, and the thickness in the Y direction of the insulating layer OLx covering the end surface of the core layer OLc facing the side wall of the plate-shaped contact LI are substantially equal. The thicknesses of the insulating layers OLx are preferably equal to or more than the thickness of the core layer OLc.

Note that, in the present specification, the fact that the layer thickness of a predetermined layer is substantially uniform or equal means at least one of the fact that the layer thickness of the predetermined layer is set to be uniform or equal in design and the fact that the layer thickness of the predetermined layer is uniform or equal within a range of an allowable manufacturing error.

The core layer OLc has a high Young's modulus, but is inferior in withstand voltage to the insulating layer OLx. Since the insulating layer OLx contains more Si—O bonds than the core layer OLc and is formed to have a thickness equal to or greater than that of the core layer OLc, the withstand voltage of the entire insulating layers OL can be increased, and a leakage current between layers such as the word lines WL can be suppressed.

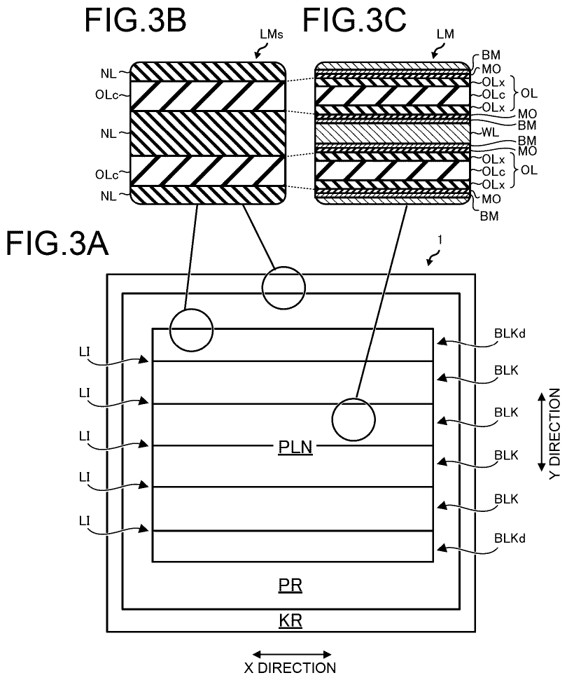

As described above, the semiconductor memory device 1 of the first embodiment includes the stacked body LM having the above-described layer structure. In addition, the semiconductor memory device 1 of the first embodiment may have a stacked body having a layer structure different from the above. Such a stacked body LMs will be described with reference to FIGS. 3A to 3C.

FIGS. 3A to 3C are schematic views describing stacked bodies LM and LMs included in the semiconductor memory device 1 according to the first embodiment. More specifically, FIG. 3A is a schematic plan view illustrating a layout of the semiconductor memory device 1, and FIGS. 3B and 3C are cross-sectional views illustrating layer structures of stacked bodies LMs and LM included in the semiconductor memory device 1, respectively.

As illustrated in FIG. 3A, the semiconductor memory device 1 is singulated and formed into a chip shape. A plane PLN including various configurations such as the stacked body LM, the pillars PL, the plate-shaped contacts LI, and the contacts CC is disposed in a central part of the singulated semiconductor memory device 1. Although only one plane PLN is illustrated in the examples of FIGS. 3A to 3C, the semiconductor memory device 1 may include a plurality of planes PLN. The plane PLN is an element of the semiconductor memory device 1 that can operate independently of another plane PLN.

The stacked body LM included in the plane PLN is divided by the plurality of plate-shaped contacts LI as described above, and the block regions BLK are disposed between the adjacent plate-shaped contacts LI. However, dummy block regions BLKd that do not function as the block regions BLK are disposed at both end portions in the Y direction, that is, further outside the plate-shaped contacts LI closest to both end portions in the Y direction of the stacked body LM.

The peripheral region PR is disposed around the plane PLN so as to surround the plane PLN. The kerf region KR is disposed further outside the peripheral region PR so as to surround the plane PLN via the peripheral region PR.

As illustrated in FIG. 3C, the stacked body LM included in the plane PLN includes the plurality of insulating layers OL disposed between the plurality of word lines WL and having a three-layer structure of the insulating layer OLx/the core layer OLc/the insulating layer OLx, as described above.

As illustrated in FIG. 3B, in some cases, the stacked body LMs having a layer structure different from that of the stacked body LM is disposed at both end portions in the Y direction of the stacked body LM included in the plane PLN, that is, in at least a partial region of the dummy block regions BLKd. The stacked body LMs has a configuration in which a plurality of insulating layers NL and a plurality of core layers OLc are alternately stacked one by one.

The plurality of insulating layers NL is, for example, silicon nitride layers or the like, and is disposed at height positions corresponding to the word lines WL and the select gate lines SGD and SGS of the stacked body LM. Each of the insulating layers NL has a thickness equal to or larger than the thickness including each of the word lines WL and the barrier metal layers BM and the metal element-containing layers MO disposed above and below the word line WL in the stacked body LM in the stacking direction.

The plurality of core layers OLc is, for example, carbon-doped silicon oxide layers or the like containing a material similar to that of the core layer OLc of the stacked body LM, and is disposed at height positions corresponding to the core layers OLc of the stacked body LM. Each of the core layers OLc included in the stacked body LMs has a thickness exceeding the thickness of each of the core layers OLc included in the stacked body LM in the stacking direction. However, the thickness of the core layer OLc in the stacked body LMs in the stacking direction is equal to or less than the thickness including the core layer OLc and the insulating layers OLx disposed above and below the core layer OLc in the stacked body LM.

In addition, the above-described stacked body LMs can also be disposed in at least a part of the kerf region KR. As described above, the kerf region KR is used as a dicing line when the semiconductor memory device 1 is singulated. Therefore, although a part or the whole of the kerf region KR disappears from the semiconductor memory device 1 after singulation, the stacked body LMs in the kerf region KR separated from the stacked body LM may remain even after singulation in the process for manufacturing the semiconductor memory device 1.

### (Method for Manufacturing Semiconductor Memory Device)

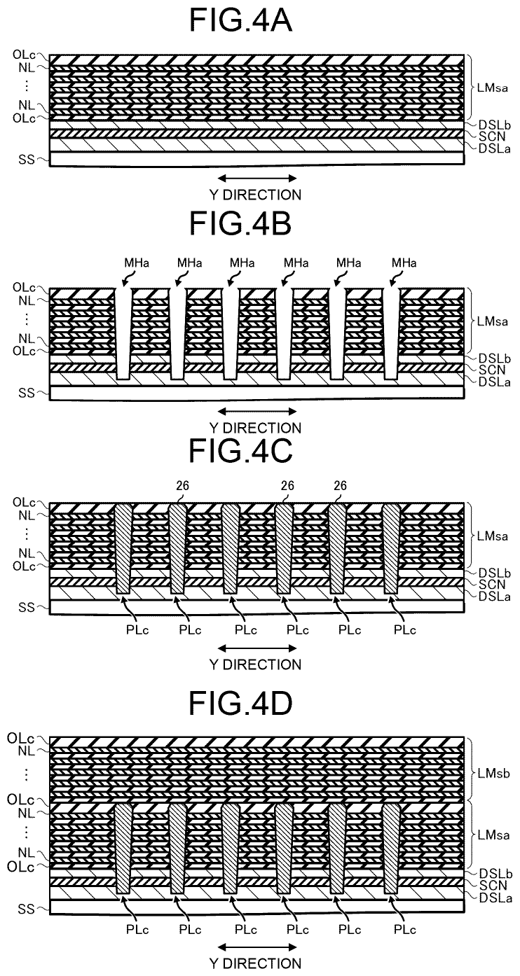

Next, a method for manufacturing the semiconductor memory device 1 of the first embodiment will be described with reference to FIGS. 4A to 14C. FIGS. 4A to 14C are views sequentially illustrating a part of a procedure of a method for manufacturing the semiconductor memory device 1 according to the first embodiment.

FIGS. 4A to 8C are cross-sectional views along the Y direction of a region that becomes the memory region MR later.

As illustrated in FIG. 4A, a lower source line DSLa, an intermediate sacrificial layer SCN, and an upper source line DSLb are formed in this order on a support substrate SS.

As the support substrate SS, a semiconductor substrate such as a silicon substrate, an insulating substrate such as a ceramic substrate, a conductive substrate, or the like can be used. The insulating layer 60 (see FIG. 2A or the like) described above may be formed on the upper surface side of the support substrate SS. The intermediate sacrificial layer SCN is, for example, a silicon nitride layer or the like, and is a layer that is replaced with a polysilicon layer or the like later and becomes the intermediate source line BSL.

A stacked body LMsa in which a plurality of insulating layers NL and a plurality of core layers OLc are alternately stacked one by one is formed on the upper source line DSLb. The insulating layers NL are, for example, silicon nitride layers or the like, and function as sacrificial layers that are later replaced with conductive materials and become the word lines WL or the select gate lines SGS. The core layers OLc can be formed by depositing silicon oxide layers by a chemical vapor deposition (CVD) method or the like while performing doping with carbon. At this time, it is preferable to adjust the doping amount of carbon so that the content of carbon in the core layer OLc is 1 atom % or more.

Thereafter, although not illustrated, the insulating layers NL and the core layers OLc are processed into a staircase shape in a partial region of the stacked body LMsa. Such processing can be performed by repeating slimming of a mask pattern such as a photoresist layer and etching of the insulating layers NL and the core layers OLc of the stacked body LMsa a plurality of times.

That is, a mask pattern is formed on the upper surface of the stacked body LMsa, and the insulating layer NL and the core layer OLc in an exposed portion are etched away one by one. In addition, an end portion of the mask pattern is retracted by treatment with oxygen plasma or the like to newly expose the upper surface of the stacked body LMsa, and the insulating layer NL and the core layer OLc are further etched away one by one. By repeating such treatment a plurality of times, the stacked body LMsa having a staircase shape is formed at both end portions in the X direction and both end portions in the Y direction.

In addition, as a result, the stacked body LMsa is separated into the stacked body LMsa at a central part where the pillars PL, the contacts CC, and the like are formed later to become the stacked body LMa, and the stacked body LMsa at an outer edge part disposed in the kerf region KR (see FIG. 3A or the like) so as to be separated from the central part and surround the stacked body LMsa at the central part.

As illustrated in FIG. 4B, a plurality of memory holes MHa extending through the stacked body LMsa in the stacking direction is formed. The plurality of memory holes MHa penetrates the stacked body LMsa, the upper source line DSLb, and the intermediate sacrificial layer SCN and reaches the lower source line DSLa. These memory holes MHa are portions that later become lower structures of the pillars PL.

As illustrated in FIG. 4C, the memory holes MHa are filled with sacrificial layers 26 such as amorphous silicon layers or CVD-carbon layers. As a result, pillars PLc in which the plurality of memory holes MHa is filled with the sacrificial layers 26 are formed.

As illustrated in FIG. 4D, a stacked body LMsb that covers the stacked body LMsa and in which a plurality of insulating layers NL and a plurality of core layers OLc are alternately stacked one by one is formed. The insulating layers NL of the stacked body LMsb function as sacrificial layers that are later replaced with conductive layers and become the word lines WL or the select gate lines SGD.

Thereafter, although not illustrated, the insulating layers NL and the core layers OLc are processed into a staircase shape in a partial region of the stacked body LMsb. Such processing can be performed by repeating slimming of a mask pattern such as a photoresist layer and etching of the insulating layers NL and the core layers OLc of the stacked body LMsb a plurality of times similarly to the treatment on the stacked body LMsa described above.

At this time, the uppermost step of the stair part formed in the stacked body LMsa and the lowermost step of the stair part formed in the stacked body LMsb are brought close to each other to form a staircase shape continuously from the lower layer side of the stacked body LMsa to the upper layer side of the stacked body LMsb. As a result, the stacked bodies LMsa and LMsb are formed in which the staircase regions SR having a staircase shape from the stacked body LMsa to the stacked body LMsb are formed at both end portions in the X direction and both end portions in the Y direction.

In addition, as a result, the stacked body LMsb is separated into the stacked body LMsb at a central part where the pillars PL, the contacts CC, and the like are formed later to become the stacked body LMb, and the stacked body LMsb at an outer edge part disposed in the kerf region KR (see FIG. 3A or the like) so as to be separated from the central part and surround the stacked body LMsb at the central part.

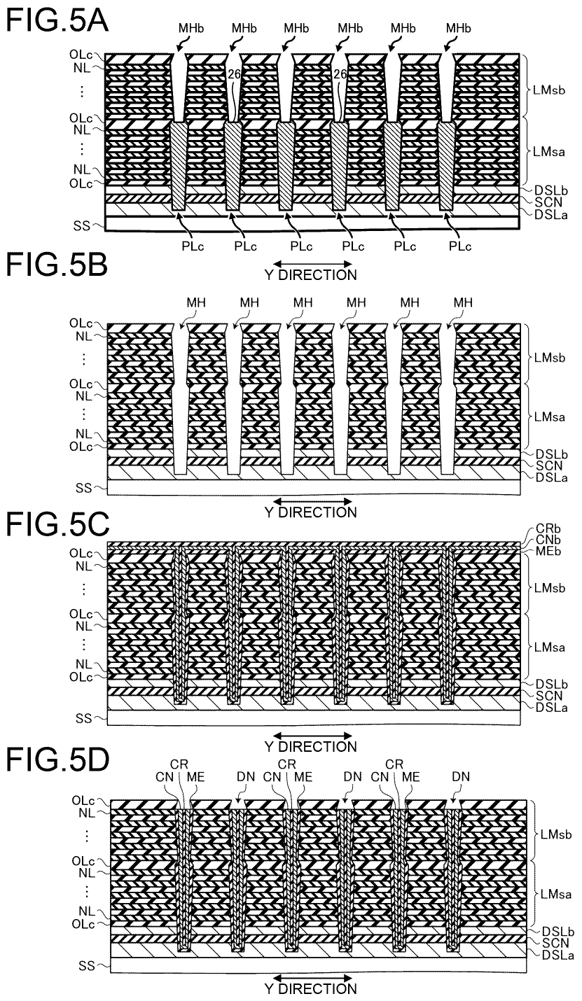

As illustrated in FIG. 5A, a plurality of memory holes MHb penetrating the stacked body LMsb and connected to the plurality of pillars PLc formed in the stacked body LMsa are formed. The memory holes MHb are portions that later become upper structures of the pillars PL.

As illustrated in FIG. 5B, the sacrificial layers 26 are removed from the pillars PLc at the bottoms of the memory holes MHb. As a result, the memory holes MHa are opened at the bottoms of the plurality of memory holes MHb, and a plurality of memory holes MH penetrating the stacked bodies LMsb and LMsa, the upper source line DSLb, and the intermediate sacrificial layer SCN and reaching the lower source line DSLa is formed.

Note that, in a case where the sacrificial layers 26 loaded in the pillars PLc are CVD-carbon layers or the like, the sacrificial layers 26 can be collectively removed from these pillars PLc when the mask pattern or the like used at the time of forming the memory holes MHb in FIG. 5A described above is removed by ashing or the like using oxygen plasma.

As illustrated in FIG. 5C, a multilayer insulating layer MEb, a semiconductor layer CNb, and an insulating layer CRb are formed in this order in the memory holes MH. As a result, the multilayer insulating layer MEb and the semiconductor layer CNb are disposed on the side surfaces of the memory holes MH and the bottom surfaces where the lower source line DSLa is exposed, and the insulating layer CRb is loaded in central portions of the memory holes MH.

The multilayer insulating layer MEb is an insulating layer having a multilayer structure that becomes the memory layer ME later. The semiconductor layer CNb is a layer that becomes the channel layer CN later. The insulating layer CRb is a silicon oxide layer or the like that becomes the core layer CR later.

The multilayer insulating layer MEb, the semiconductor layer CNb, and the insulating layer CRb are also formed in this order on the upper surface of the stacked body LMsb.

As illustrated in FIG. 5D, the insulating layer CRb, the semiconductor layer CNb, and the multilayer insulating layer MEb are sequentially etched back to be removed from the upper surface of the stacked body LMsb, and recesses DN are formed at the upper end portions of the memory holes MH. As a result, the memory layers ME, the channel layers CN, and the core layers CR are formed in the memory holes MH in this order from the outer peripheral side.

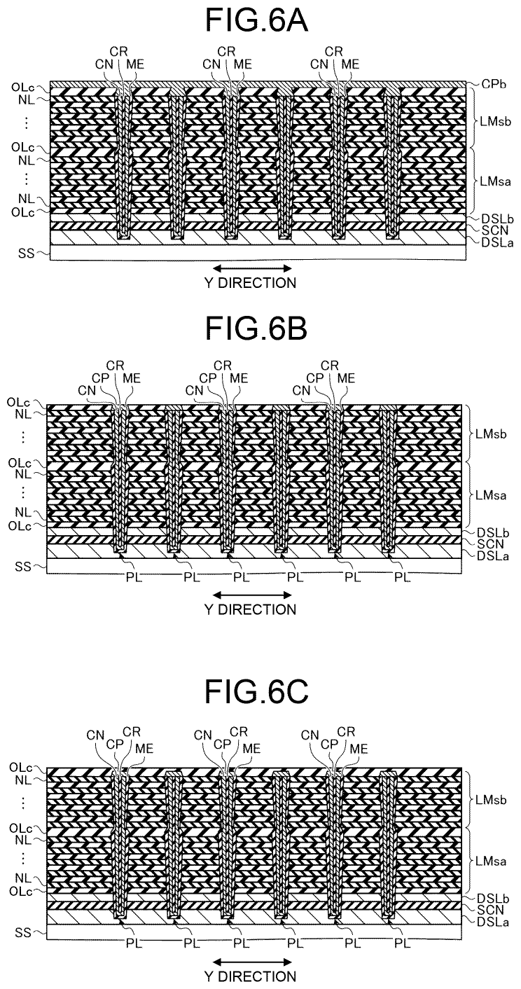

As illustrated in FIG. 6A, a semiconductor layer CPb is formed in the recesses DN at the upper end portions of the memory holes MH. The semiconductor layer CPb is a layer that becomes the cap layers CP later. The semiconductor layer CPb is also formed on the upper surface of the stacked body LMsb.

As illustrated in FIG. 6B, the semiconductor layer CPb on the upper surface of the stacked body LMsb is removed by CMP or the like, and the cap layers CP are formed at the upper end portions of the memory holes MH.

As illustrated in FIG. 6C, an uppermost core layer OLc of the stacked body LMsb thinned by CMP or the like is stacked. As a result, the pillars PL in which the cap layers CP are embedded in the uppermost core layer OLc are formed. However, at this time point, the memory layer ME covers the entire side wall of the pillar PL, and a part of the side surface of the channel layer CN is not in a state of being exposed from the memory layer ME.

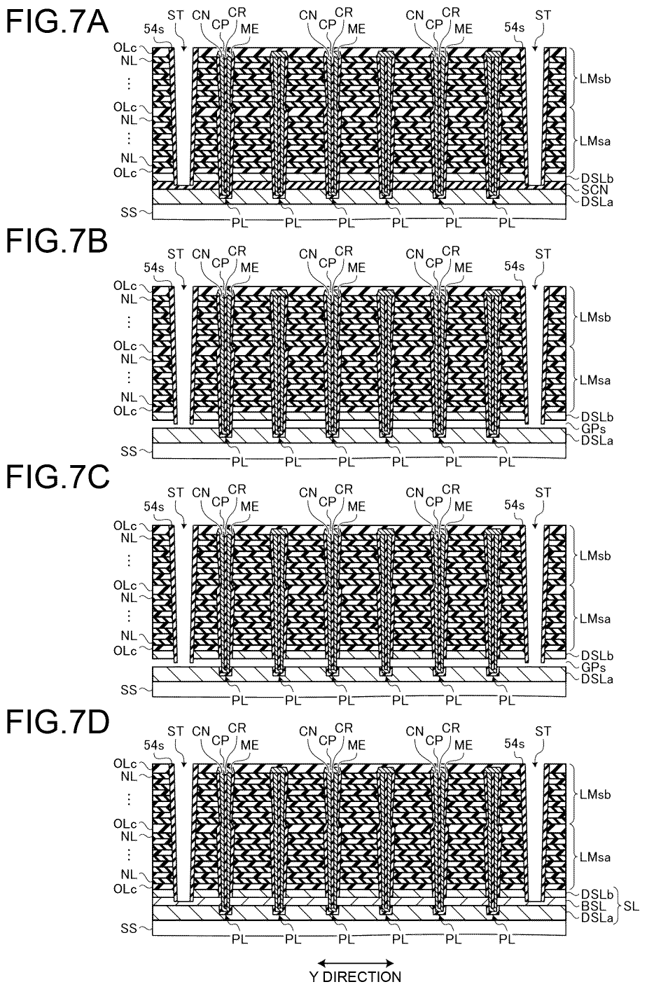

As illustrated in FIG. 7A, slits ST that penetrate the stacked bodies LMsb and LMsa and the upper source line DSLb and reach the intermediate sacrificial layer SCN are formed. In addition, insulating layers 54s are formed on the side walls of the slits ST facing each other in the Y direction. The slits ST also extend in the direction along the X direction in the stacked bodies LMsa and LMsb.

As illustrated in FIG. 7B, a removal liquid of the intermediate sacrificial layer SCN such as hot phosphoric acid is caused to flow through the slits ST whose side walls are protected by the insulating layers 54s, and the intermediate sacrificial layer SCN sandwiched between the lower source line DSLa and the upper source line DSLb is removed.

As a result, a gap layer GPs is formed between the lower source line DSLa and the upper source line DSLb. In addition, a part of the memory layer ME in the outer peripheral portions of the pillars PL is exposed in the gap layer GPs. At this time, since the side walls of the slits ST are protected by the insulating layers 54s, it is suppressed that the insulating layers NL in the stacked bodies LMsa and LMsb are also removed.

As illustrated in FIG. 7C, a chemical liquid is caused to appropriately flow into the gap layer GPs through the slits ST, and the block insulating layer BK, the charge storage layer CT, and the tunnel insulating layer TN (see FIGS. 2B and 2C) of the memory layer ME exposed in the gap layer GPs are sequentially removed. As a result, the memory layer ME is removed from partial side walls of the pillars PL, and a part of the channel layer CN on the inner side is exposed in the gap layer GPs.

As illustrated in FIG. 7D, a source gas such as amorphous silicon is injected from the slits ST whose side walls are protected by the insulating layers 54s, and the gap layer GPs is filled with amorphous silicon or the like. In addition, the support substrate SS is heat-treated to polycrystallize the amorphous silicon loaded in the gap layer GPs, thereby forming the intermediate source line BSL containing polysilicon or the like.

As a result, a part of the channel layers CN of the pillars PL is connected to the source line SL on the side surfaces via the intermediate source line BSL.

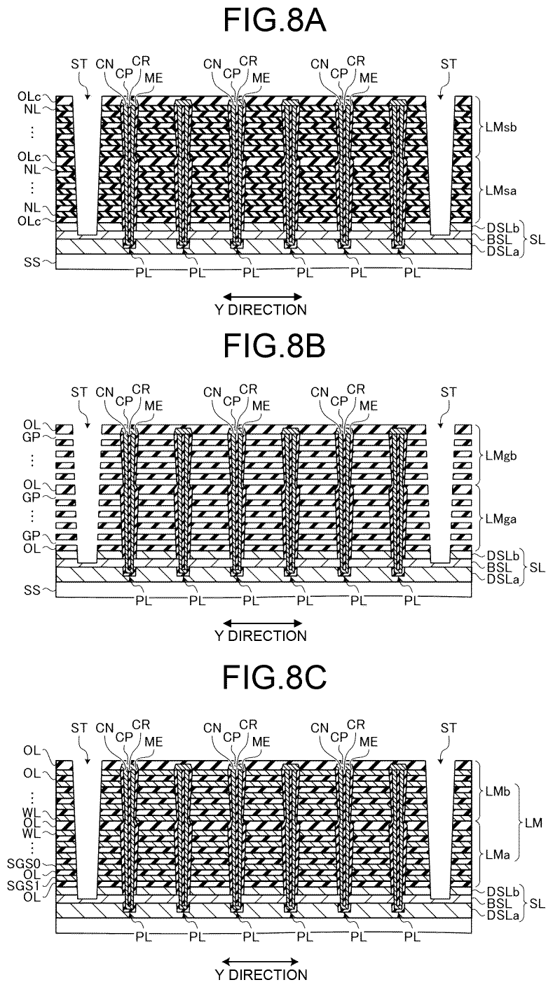

As illustrated in FIG. 8A, the insulating layers 54s on the side walls of the slits ST are temporarily removed.

As illustrated in FIG. 8B, a removal liquid of the insulating layers NL such as, for example, hot phosphoric acid is caused to flow into the stacked bodies LMsa and LMsb from the slits ST to remove the insulating layers NL of the stacked bodies LMsa and LMsb. As a result, stacked bodies LMga and LMgb including a plurality of gap layers GP from which the insulating layers NL between the core layers OLc are removed are formed.

The stacked bodies LMga and LMgb including the plurality of gap layers GP have a fragile structure. The plurality of pillars PL supports such fragile stacked bodies LMga and LMgb. In addition, the core layers OLc remaining in the stacked bodies LMga and LMgb are made of a material having a higher Young's modulus than, for example, a silicon oxide layer that is not doped with carbon, or the like.

Such a support structure of the pillars PL and the core layers OLc having a high Young's modulus suppress bending of the core layers OLc remaining in the stacked bodies LMga and LMgb and distortion or collapse of the stacked bodies LMga and LMgb.

In addition, after the insulating layers NL are removed from the stacked bodies LMsa and LMsb, the surfaces of the core layers OLc are oxidized to form the insulating layers OLx covering the upper and lower surfaces of the core layers OLc and the end surfaces facing the slits ST. As a result, the plurality of insulating layers OL having a three-layer structure of the core layer OLc and the insulating layers OLx is formed in the stacked bodies LMga and LMgb.

As illustrated in FIG. 8C, a source gas of a conductive material such as tungsten or molybdenum is injected from the slits ST into the stacked bodies LMga and LMgb, and the gap layers GP of the stacked bodies LMga and LMgb are filled with the conductive material to form the plurality of word lines WL and the like. As a result, the stacked body LM including stacked bodies LMa and LMb in which the plurality of word lines WL and the plurality of insulating layers OL are alternately stacked one by one is formed.

As described above, the treatment of forming the intermediate source line BSL from the intermediate sacrificial layer SCN and the treatment of forming the word lines WL from the insulating layers NL are also referred to as replacement treatment.

Note that, in the above-described replacement treatment of the stacked body LM, the stacked bodies LMsa and LMsb before replacement may remain in a partial region.

For example, there is a case where the removal liquid of the insulating layers NL injected from the slits ST does not permeate outer regions of the slits ST closest to both end portions in the Y direction of the stacked bodies LMsa and LMsb and close to the end positions in the Y direction of the stacked bodies LMsa and LMsb. In this case, since the insulating layers NL are not removed and the word lines WL and the like are not formed in these regions, the stacked bodies LMsa and LMsb remain while maintaining the original layer structure.

However, as described above, since the outer regions of the slits ST closest to both end portions in the Y direction of the stacked bodies LMsa and LMsb are the dummy block regions BLKd, even when the stacked bodies LMsa and LMsb remain, the characteristics of the semiconductor memory device 1 are not affected.

In addition, for example, when both end portions in the X direction and both end portions in the Y direction of the stacked bodies LMsa and LMsb are processed into a staircase shape, the outer edge parts remaining in the kerf region KR are also separated from the portions of the stacked bodies LMsa and LMsb in which the slits ST are formed, and thus remain as it is without being subjected to the replacement treatment.

Thereafter, the insulating layers 54 are formed on the side walls of the slits ST, and the insulating layers 54 are filled with the conductive layers 24 to form the plate-shaped contacts LI. However, the insulating layers 54 or the like may be loaded in the slits ST without forming the conductive layers 24 to form the plate-shaped members.

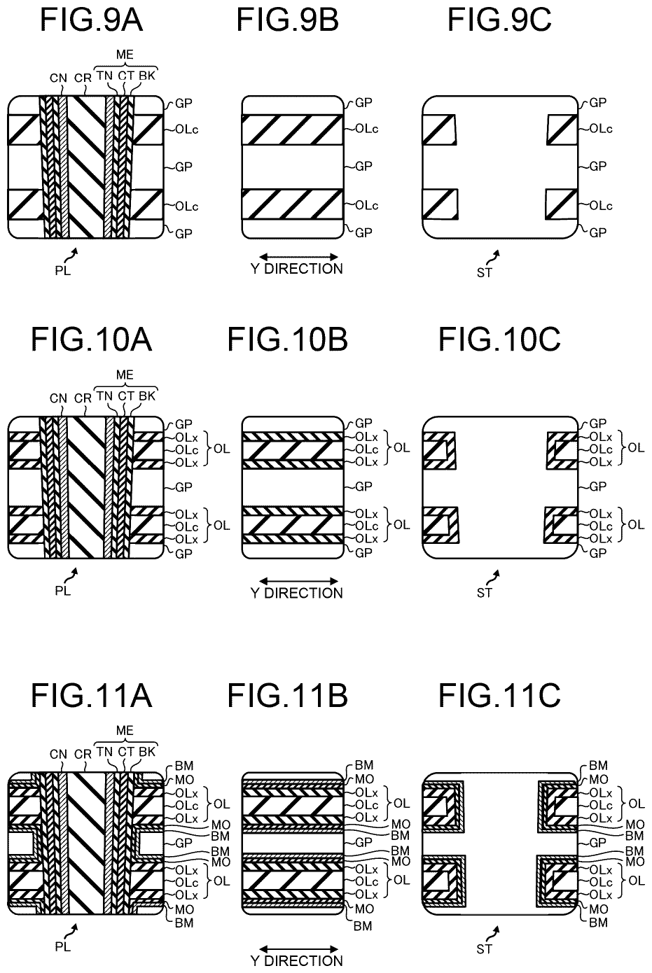

Here, FIGS. 9A to 14 C illustrate details of the replacement treatment of forming the word lines WL from the insulating layers NL.

As of FIGS. 9A to 14C are enlarged cross-sectional views of the pillar PL at the height position of the word line WL. Bs of FIGS. 9A to 14C are enlarged cross-sectional views of the stacked bodies LMga and LMgb or the stacked bodies LMa and LMb at the height position of the word line WL. Cs of FIGS. 9A to 14C are enlarged cross-sectional views of the slit ST or the plate-shaped contact LI at the height position of the word line WL.

Note that the replacement treatment described below is similarly performed in the region including the select gate lines SGD and SGS.

FIGS. 9A to 9C illustrate states of the stacked bodies LMga and LMgb after the insulating layers NL are removed through the slits ST. The gap layers GP generated by removing the insulating layers NL are formed between the plurality of core layers OLc. In removing the insulating layers NL, a removal liquid such as hot phosphoric acid is used as described above, and cleaning treatment using a predetermined cleaning liquid is performed on the stacked bodies LMga and LMgb after removal of the insulating layers NL.

Surface tension due to the removal liquid or the cleaning liquid acts on the core layers OLc in the stacked bodies LMga and LMgb, and thus, there is a concern that the core layers OLc adjacent to each other in the stacking direction may adhere to each other. However, as described above, since the core layers OLc contain a material having a high Young's modulus, such adhesion between the core layers OLc is suppressed. Similarly, the bending, distortion, and the like of the stacked bodies LMga and LMgb are also suppressed by the core layers OLc having a high Young's modulus.

On the other hand, the core layers OLc are inferior in withstand voltage to, for example, a silicon oxide layer that is not doped with carbon, or the like. Therefore, before the word lines WL and the like are formed in the gap layers GP of the stacked bodies LMga and LMgb, a treatment of increasing the withstand voltage by oxidizing the surfaces of the core layers OLc is performed.

As illustrated in FIGS. 10A to 10C, the core layers OLc are oxidized to form the insulating layers OLx on the surfaces of the core layers OLc. The surfaces of the core layers OLc can be oxidized by, for example, oxygen radical oxidation treatment or thermal oxidation treatment. The oxygen radical oxidation treatment is performed using, for example, oxygen plasma generated by a remote plasma method or a direct plasma method. The thermal oxidation treatment can be performed by, for example, a dry treatment of heating an object to be oxidized in an oxygen atmosphere or an ozone atmosphere, a wet treatment of heating an object to be oxidized in water vapor, or the like.

By oxidizing the core layers OLc in this manner, substantially the entire exposed surfaces of the core layers OLc are oxidized to form the insulating layers OLx, and the insulating layers OL having a three-layer structure of the insulating layer OLx/the core layer OLc/the insulating layer OLx are formed in the layer thickness direction.

More specifically, as illustrated in FIGS. 10A and 10B, in the vicinity of the pillar PL and in portions of the stacked bodies LMga and LMgb where the pillar PL, the slit ST, and the like do not exist, the upper and lower surfaces of the core layers OLc in the stacking direction are oxidized and covered with the insulating layers OLx. On the other hand, as illustrated in FIG. 10C, in the vicinity of the slit ST, not only the upper and lower surfaces but also end surfaces of the core layers OLc facing the slit ST are in an exposed state. Therefore, in addition to the upper and lower surfaces of the core layers OLc, the end surfaces on the slit ST side are also covered with the insulating layers OLx.

Such an oxidation treatment usually proceeds at a substantially constant speed over the entire exposed surfaces of the core layers OLc. Therefore, the insulating layers OLx covering the exposed surfaces of the core layers OLc are formed to have a substantially uniform thickness at any location. At this time, the surfaces of the core layers OLc are sufficiently oxidized such that the amount of Si—O bonds in the insulating layers OLx are larger than the amount of Si—O bonds in the core layers OLc. In addition, it is preferable to perform the oxidation treatment until the core layers OLc remaining without being oxidized have a layer thickness equal to or less than that of the insulating layers OLx on the surfaces of the core layers OLc.

As a result, a sufficient withstand voltage is obtained as the entire insulating layers OL.

Note that the insulating layers OLx formed by the oxidation treatment may volumetrically expand more than the original core layers OLc. This is why the layer thickness of the entire insulating layer OL having a three-layer structure of the insulating layer OLx/the core layer OLc/the insulating layer OLx after the oxidation treatment can be equal to or larger than the layer thickness of the core layer OLc before the oxidation treatment.

As illustrated in FIGS. 11A to 11C, the metal element-containing layers MO and the barrier metal layers BM are formed in this order through the slit ST in the gap layers GP of the stacked bodies LMga and LMgb. The metal element-containing layers MO and the barrier metal layers BM are formed on the upper and lower surfaces of the insulating layers OL exposed in the gap layers GP, the end surfaces of the insulating layers OL facing the slit ST, and the side walls of the pillar PL exposed in the gap layers GP. That is, the metal element-containing layers MO and the barrier metal layers BM are formed at the height positions of the gap layers GP where the word lines WL and the like are to be formed later in the side wall portions of the pillar PL, and are formed at the height positions of the insulating layers OL in the side wall portions of the slit ST.

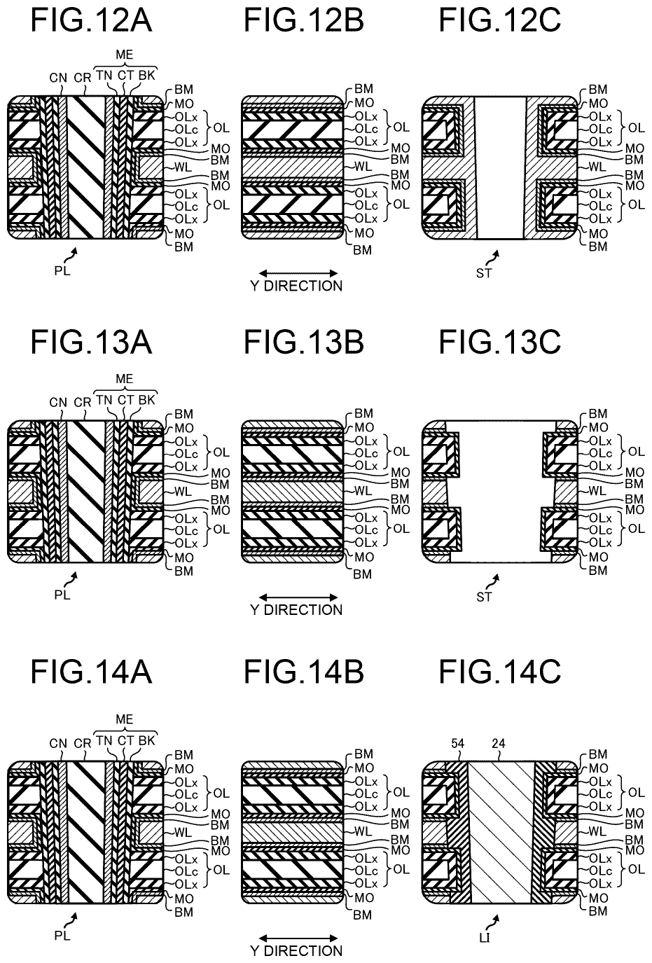

As illustrated in FIGS. 12A to 12C, the gap layers GP of the stacked bodies LMga and LMgb in which the metal element-containing layers MO and the barrier metal layers BM are formed are filled with a conductive material such as tungsten or molybdenum through the slit ST to form the word lines WL or the like. At this time, a conductive material is also formed in a part of the slit ST.

As illustrated in FIGS. 13A to 13C, the conductive material formed in the slit ST is removed. In addition, the barrier metal layers BM covering the end surfaces of the insulating layers OL facing the slit ST are removed. At this time, in order to completely remove the barrier metal layers BM from the end surfaces of the insulating layers OL, a part or the whole of the metal element-containing layers MO on the end surfaces of the insulating layers OL may be removed. In addition, at this time, the end surfaces of the word lines WL exposed in the slit ST may retract in a direction away from the side wall of the slit ST together with the barrier metal layers BM covering the upper and lower surfaces of the word lines WL.

By removing the barrier metal layers BM from the end surfaces of the insulating layers OL, conduction through the barrier metal layers BM between the word lines WL adjacent in the stacking direction can be suppressed.

As illustrated in FIGS. 14A to 14C, the insulating layers 54 are formed on the side walls of the slit ST, and the inside of the slit ST is filled with the conductive layer 24. Thus, the plate-shaped contact LI is formed. Note that when the barrier metal layers BM are removed from the end surfaces of the insulating layers OL, the word lines WL and the like retract, so that the insulating layers 54 on the side walls of the plate-shaped contact LI may have a shape protruding in the direction of the word line WL at the height position of the word line WL and the like.

Thereafter, grooves penetrating one or a plurality of conductive layers including the uppermost conductive layer of the stacked body LMb are formed, and the insulating layers 56 are loaded in the grooves to form the separation layers SHE that partition these conductive layers into the pattern of the select gate lines SGD.

In addition, the plurality of contacts CC reaching the word lines WL and the select gate lines SGD and SGS constituting the steps of the staircase structure of the staircase regions SR are formed from the upper side of the staircase regions SR.

In addition, the insulating layer 52 is formed on the upper surface of the stacked body LM, and the plugs CH connected to the pillars PL and plugs connected to the contacts CC are formed by penetrating the insulating layer 52. Further, the insulating layer 53 is formed on the insulating layer 52, and the bit line BL connected to the plugs CH, the upper layer wiring connected to the contacts CC via the plugs, and the like are formed. In addition, an electrode pad or the like for having electrical conduction with the peripheral circuits CBA is formed on the upper surface of the insulating layer 53.

Note that, for example, the plugs CH, the bit line BL, and the like may be collectively formed by using a dual damascene method or the like.

In addition, the peripheral circuits CBA are formed on the semiconductor substrate SB separate from the support substrate SS on which the stacked body LM is formed, and is covered with the insulating layer 40. In the insulating layer 40, contacts, vias, wiring, or the like that lead the peripheral circuits CBA to the surface of the insulating layer 40 are formed and connected to the electrode pad or the like formed on the upper surface of the insulating layer 40.

Subsequently, the support substrate SS and the semiconductor substrate SB are bonded to each other by the insulating layers 50 and 40, and the electrode pads in the insulating layers 50 and 40 are connected. Thereafter, the support substrate SS is removed to expose the source line SL, and the electrode film EL is connected via the insulating layer 60 in which the plugs PG are formed.

Thus, the semiconductor memory device 1 of the first embodiment is manufactured.

In the process for manufacturing a semiconductor memory device such as a three-dimensional nonvolatile memory, a stacked body in which a conductive layer and an insulating layer are stacked may be formed by replacing a sacrificial layer in the stacked body with the conductive layer. In this case, the fragile stacked body including a plurality of gap layers may be bent or distorted during the replacement treatment.

In order to suppress this, it is conceivable that an insulator disposed between sacrificial layers has a three-layer structure in which a non-doped silicon oxide layer is sandwiched between carbon-doped silicon oxide layers having a high Young's modulus, thereby achieving both sufficient strength and withstand voltage. However, in order to form an insulating layer having a three-layer structure, for example, it is necessary to perform film formation in the order of a carbon-doped silicon oxide layer, a non-doped silicon oxide layer, and a carbon-doped silicon oxide layer every time each insulator between sacrificial layers is formed, and to perform film formation by switching a gas type a plurality of times, and there is a concern about a decrease in throughput.

With the semiconductor memory device 1 of the first embodiment, the core layers OLc including the Si—C bond and the insulating layers OLx including the Si—O bond and covering the upper and lower surfaces of the core layers OLc in the stacking direction and the end surfaces of the core layers OLc facing the side walls of the plate-shaped contacts LI are disposed as insulators between the plurality of word lines WL.

As a result, the Young's modulus of the core layer OLc can be made higher than that of the insulating layer OLx, and bending and distortion of the stacked bodies LMga and LMgb during the replacement treatment can be suppressed. In addition, by the insulating layers OLx covering the core layers OLc, the withstand voltage of the entire insulating layers OL can be increased, and the leakage current and the like between the word lines WL can be suppressed. By sandwiching the word lines WL and the like with the insulating layers OL having an increased withstand voltage as a whole, the leakage current between the word lines WL and the plate-shaped contacts LI can also be suppressed.

With the semiconductor memory device 1 of the first embodiment, the thickness of the insulating layers OLx in the stacking direction is desirably equal to or greater than the thickness of the core layers OLc in the stacking direction. As a result, the insulating layers OL as a whole have a more sufficient withstand voltage.

With the semiconductor memory device 1 of the first embodiment, the insulating layers OLx are oxide layers of the core layers OLc. As described above, when the removal liquid or the cleaning liquid is used at the time of the replacement treatment of the stacked body LMs, the bending and distortion of the stacked body LMs can be suppressed by the core layers OLc before the oxidation treatment, and thereafter, by oxidizing the surfaces of the core layers OLc before forming the word lines WL and the like, the insulating layers OL having a sufficient withstand voltage can be obtained without a decrease in throughput.

### Second Embodiment

Hereinafter, a second embodiment will be described in detail with reference to the drawings. A semiconductor memory device 2 of the second embodiment is different from that of the first embodiment described above in disposition position of a memory region MR and staircase regions SR in a stacked body LM and a peripheral circuit CUA with respect to the stacked body LM.

In the drawings described below, the same reference numerals are given to the same configurations as those of the first embodiment described above, and the description thereof may be omitted.

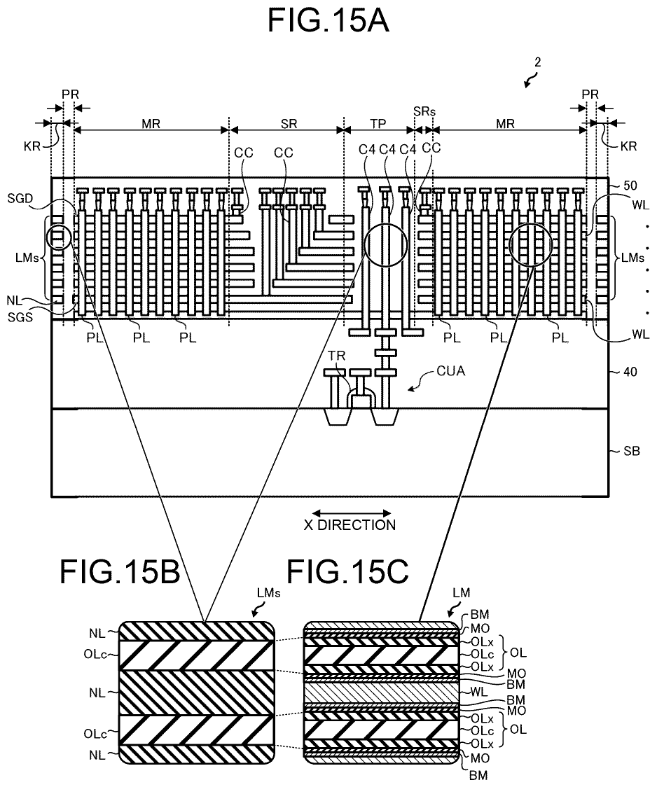

FIGS. 15A and 15C are views illustrating a schematic configuration example of a semiconductor memory device 2 according to a second embodiment. More specifically, FIG. 15A is a cross-sectional view along an X direction of the semiconductor memory device 2, and FIGS. 15B and 15C are cross-sectional views illustrating layer structures of stacked bodies LMs and LM included in the semiconductor memory device 2, respectively.

As illustrated in FIG. 15A, the semiconductor memory device 2 of the second embodiment includes the peripheral circuit CUA and the stacked body LM including a plurality of word lines WL and the like in this order on a substrate SB.

The substrate SB is, for example, a semiconductor substrate such as a silicon substrate. On the substrate SB, the peripheral circuit CUA that includes a transistor TR, wiring, and the like and controls an electrical operation of memory cells MC of the semiconductor memory device 2 is disposed.

The peripheral circuit CUA is covered with an insulating layer 40 such as a silicon oxide film. A source line SL is disposed on the insulating layer 40. The stacked body LM in which the plurality of word lines WL, and select gate lines SGD and SGS are stacked is disposed above the source line SL.

In the stacked body LM, a plurality of memory region MR, staircase regions SR and SRs, and a penetrating contact region TP are disposed. The staircase regions SR and SRs and the penetrating contact region TP are disposed at a central part of the stacked body LM, and the memory regions MR are disposed on both sides of the staircase regions SR and SRs and the penetrating contact region TP in an X direction.

In the memory regions MR, a plurality of pillars PL penetrating the plurality of word lines WL in the stacking direction is disposed. A plurality of memory cells MC (see FIG. 2C) is formed at intersection portions of the pillars PL and the word lines WL. As a result, the semiconductor memory device 2 of the second embodiment is also configured as a three-dimensional nonvolatile memory in which the plurality of memory cells MC is three-dimensionally disposed.

The staircase region SR includes a plurality of stair parts in which the plurality of word lines WL and the like are dug down in a valley shape in the stacking direction. The word lines WL and the select gate lines SGD and SGS of the layers maintain electrical conduction on both sides in the X direction across the staircase region SR via an end portion on the Y direction side of the staircase region SR.

The contacts CC connected to the word lines WL and the select gate lines SGS among the word lines WL and the select gate lines SGD and SGS processed into a staircase shape are disposed in a stair part closer to the penetrating contact region TP on one side in the X direction, and the contacts CC connected to the select gate lines SGD are disposed closer to the memory region MR on the other side in the X direction.

In addition, the staircase region SRs in which the contacts CC are connected to the select gate lines SGD is further provided between the penetrating contact region TP and the memory region MR.

The contacts CC connected to the word lines WL and the select gate lines SGD and SGS of the staircase regions SR and SRs are electrically connected to upper layer wiring further above the select gate lines SGD, and the peripheral circuit CUA via penetrating contacts C4 described below, and the like.

In the penetrating contact region TP, the penetrating contacts C4 penetrating the penetrating contact region TP in the stacked body LM are disposed. The penetrating contacts C4 connect the peripheral circuit CUA disposed on the substrate SB below and the contacts CC provided at the plurality of word lines WL. Various voltages applied from the contacts CC to the memory cells MC are controlled by the peripheral circuit CUA via the penetrating contacts C4 and the like.

The stacked body LM having the above configuration is covered with an insulating layer 50. The insulating layer 50 also extends around the plurality of stacked bodies LM. A peripheral region PR is disposed around the stacked bodies LM, and a kerf region KR is disposed further outside the peripheral region PR and at an end portion of the singulated semiconductor memory device 2.

As illustrated in FIG. 15C, the stacked bodies LM included in the semiconductor memory device 2 have a layer structure similar to that of the stacked body LM of the embodiment described above.

As illustrated in FIG. 15B, in the penetrating contact region TP, instead of the stacked body LM, a stacked body LMs in which a plurality of insulating layers NL and a plurality of core layers OLc are alternately stacked one by one is disposed. That is, the stacked body LMs is disposed in the penetrating contact region TP with both sides sandwiched or surrounded by the stacked bodies LM. Such a stacked body LMs is formed by providing barriers between both end portions of the penetrating contact region TP in the Y direction and slits on the outer sides thereof to shield the removal liquid of the insulating layers NL injected from the slits, thereby providing a region not subjected to the replacement treatment.

The penetrating contacts C4 penetrate the stacked body LMs having no word lines WL and the like and are electrically connected to the peripheral circuit CUA below the stacked bodies LM and LMs. As a result, for example, conduction between the penetrating contacts C4 and the word lines WL and the like in the stacked bodies LM is suppressed.

In addition, as in the first embodiment described above, the stacked body LMs can also be disposed in at least a part of the kerf region KR. The stacked body LMs in the kerf region KR is also a portion that is separated from the stacked body LMs at the central part where the pillars PL and the like are disposed in the process for manufacturing the semiconductor memory device 2 and maintains the original layer structure without being subjected to the replacement treatment.

In addition, as in the first embodiment described above, the stacked body LMs may be disposed at both end portions of the stacked body LM in the Y direction.

Note that, in the first and second embodiments described above, the core layers OLc included in the stacked body LM of the semiconductor memory devices 1 and 2 are carbon-doped silicon oxide layers, and the insulating layers OLx are oxidized layers of the core layers OLc. However, the core layer having a Young's modulus higher than that of the silicon oxide layer or the like is not limited to the above, and may be, for example, a silicon carbide layer or a silicon layer. The bending, distortion, and the like of the stacked body LM are also suppressed by such core layers OLc having a high Young's modulus.

When the core layer is a silicon carbide layer, as in the first and second embodiments described above, the layers can be configured such that the content of Si—C bonds in the core layer is larger than the content of Si—C bonds in the insulating layer obtained by oxidizing the core layer, and the content of Si—O bonds in the insulating layer is larger than the content of Si—O bonds in the core layer.

When the core layer is a silicon layer, the layers can be configured such that the content of Si—Si bonds in the core layer is larger than the content of Si—Si bonds in the insulating layer obtained by oxidizing the core layer, and the content of Si—O bonds in the insulating layer is larger than the content of Si—O bonds in the core layer.

In addition, in the first and second embodiments described above, the semiconductor memory devices 1 and 2 include the stacked body LM having a two-tier structure in which two stacked bodies LMa and LMb are stacked up and down. However, the configuration of the stacked body is not limited to two tiers, and may be one tier or three tiers or more.

In addition, in the first and second embodiments described above, the pillars PL are connected to the source line SL on the side surface of the channel layer CN, but it is not limited thereto. For example, the pillar may be configured to be connected to the source line at the lower end portion of the channel layer by removing the memory layer on the bottom surface of the pillar.

In addition, in the first and second embodiments described above, the peripheral circuits CBA and CUA are disposed above or below the stacked body LM. However, the peripheral circuit may be disposed in the same layer as the stacked body. In this case, the stacked body can be formed at a position different from the peripheral circuit on the semiconductor substrate on which the peripheral circuit is formed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first stacked body in which a plurality of conductive layers is stacked apart from each other in a stacking direction;
a plate-shaped portion that extends in the first stacked body in the stacking direction and in a first direction intersecting the stacking direction, the plate-shaped portion dividing the first stacked body in a second direction intersecting the stacking direction and the first direction; and
a pillar that extends in the first stacked body in the stacking direction and in which a memory cell is formed at each of intersection portions with at least some of the plurality of conductive layers, wherein
between each of the plurality of conductive layers, a first layer and a first insulating layer are disposed, the first layer including at least one of a Si—C bond or a Si—Si bond, the first insulating layer including a Si—O bond, the first insulating layer covering upper and lower surfaces of the first layer along the stacking direction and an end surface of the first layer facing a side wall of the plate-shaped portion,
the first layer includes Si—C bonds more than the first insulating layer or the first layer includes Si—Si bonds more than the first insulating layer, and
the first insulating layer includes Si—O bonds more than the first layer.

2. The semiconductor memory device according to claim 1, wherein
the first layer is in contact with a side wall of the pillar without interposing the first insulating layer.

3. The semiconductor memory device according to claim 1, further comprising:
a metal element-containing layer that covers a facing surface of each of the first insulating layers facing the plurality of conductive layers, and covers a facing surface of the first insulating layer covering the end surface of the first layer facing the plate-shaped portion.

4. The semiconductor memory device according to claim 1, wherein
a thickness of the first insulating layer in the stacking direction is equal to or greater than a thickness of the first layer in the stacking direction.

5. The semiconductor memory device according to claim 1, wherein
a thickness of the first insulating layer disposed on the upper surface of the first layer in the stacking direction,
a thickness of the first insulating layer disposed on the lower surface of the first layer in the stacking direction, and
a thickness of the first insulating layer disposed on the end surface of the first layer in the second direction are substantially equal.

6. The semiconductor memory device according to claim 1, further comprising:
a second stacked body in which a plurality of second insulating layers and a plurality of second layers are alternately stacked, the plurality of second layers including at least one of a Si—C bond or a Si—Si bond, wherein
the plurality of second insulating layers is disposed at height positions respectively corresponding to heights of the plurality of conductive layers in the stacking direction, and
the plurality of second layers is disposed at height positions respectively corresponding to heights of the first layers disposed between the plurality of conductive layers in the stacking direction.

7. The semiconductor memory device according to claim 6, wherein
the second stacked body is disposed in contact with an end portion of the first stacked body in the second direction.

8. The semiconductor memory device according to claim 6, wherein
the second stacked body is disposed apart from the first stacked body in at least a part of a kerf region disposed so as to surround a periphery of the first stacked body.

9. The semiconductor memory device according to claim 6, further comprising:
a peripheral circuit that is disposed below the first stacked body and electrically operates the memory cell; and
a penetrating contact that extends in the stacking direction at a height position of the first stacked body, the penetrating contact being electrically connected to the peripheral circuit, wherein
the second stacked body is sandwiched or surrounded by the first stacked bodies and disposed in a region in which the penetrating contact extends in the stacking direction.

10. The semiconductor memory device according to claim 6, wherein
a thickness of the first layer in the stacking direction is less than a thickness of the second layer disposed at a corresponding height position among the plurality of second layers in the stacking direction.

11. The semiconductor memory device according to claim 6, wherein
a thickness including the first layer and the first insulating layers above and below the first layer is equal to or greater than a thickness of the second layer disposed at a corresponding height position among the plurality of second layers in the stacking direction.

12. The semiconductor memory device according to claim 1, wherein
the first layer has a Young's modulus higher than a Young's modulus of the first insulating layer.

13. The semiconductor memory device according to claim 1, wherein
the first layer contains at least one of silicon, silicon carbide, or silicon carbonate.

14. The semiconductor memory device according to claim 13, wherein
the first insulating layer is an oxide layer of the first layer.

15. A semiconductor memory device comprising:
a first stacked body in which a plurality of conductive layers is stacked with an insulator interposed therebetween in a stacking direction;
a plate-shaped portion that extends in the first stacked body in the stacking direction and in a first direction intersecting the stacking direction, the plate-shaped portion dividing the first stacked body in a second direction intersecting the stacking direction and the first direction; and
a pillar that extends in the first stacked body in the stacking direction and in which a memory cell is formed at each of intersection portions with at least some of the plurality of conductive layers, wherein
the insulator includes a first insulating layer and a first layer positioned inside the first insulating layer in the stacking direction, the first layer having a Young's modulus higher than a Young's modulus of a first insulating layer,
an end surface of the first layer facing a side wall of the plate-shaped portion is covered with the first insulating layer, and
an end surface of the first layer facing a side wall of the pillar is in contact with the side wall of the pillar without interposing the first insulating layer.

16. The semiconductor memory device according to claim 15, wherein
the first insulating layer covers upper and lower surfaces of the first layer, and covers the end surface facing the side wall of the plate-shaped portion both at a substantially uniform thickness.

17. The semiconductor memory device according to claim 15, further comprising:
a second stacked body in which a plurality of second insulating layers and a plurality of second layers that are alternately stacked, the plurality of second layers having a Young's modulus higher than a Young's modulus of the first insulating layer, wherein
the plurality of second insulating layers is disposed at height positions respectively corresponding to heights of the plurality of conductive layers in the stacking direction, and
each of the plurality of second layers is disposed at a height position corresponding to a height of the insulator in the stacking direction.

18. The semiconductor memory device according to claim 17, wherein
the plurality of second layers contains a same material as the first layer.

19. The semiconductor memory device according to claim 17, wherein
a thickness of the first layer in the insulator in the stacking direction is less than a thickness of the second layer disposed at a corresponding height position among the plurality of second layers in the stacking direction.

20. The semiconductor memory device according to claim 17, wherein
a thickness of the first insulating layer including the first layer in the insulator is equal to or greater than a thickness of the second layer disposed at a corresponding height position among the plurality of second layers in the stacking direction.
